(19) United States
(12) Patent Application Publication
(10) Pub. No.: US 2026/0164738 A1
(43) Pub. Date: Jun. 11, 2026

(54) SEMICONDUCTOR STRUCTURE AND FABRICATING METHOD THEREOF

(71) Applicant: HON HAI PRECISION INDUSTRY CO., LTD., New Taipei City (TW)

(72) Inventor: Chih-Yen SHEN, Hsinchu City (TW)

(21) Appl. No.: 19/057,939

(22) Filed: Feb. 19, 2025

(30) Foreign Application Priority Data
Dec. 6, 2024 (TW) 113147486

(51) Int. Cl. H10D 62/815; H01L 21/02; H10D 62/85

(52) U.S. Cl. CPC H10D 62/815; H10D 62/8503; H10P 14/3206; H10P 14/3216; H10P 14/3252; H10P 14/3406; H10P 14/3416

(57) ABSTRACT

A semiconductor structure includes a substrate, a superlattice structure disposed on the substrate, and a group III nitride structure disposed on the superlattice structure. The superlattice structure includes a plurality of first group III nitride layers and a plurality of second group III nitride layers of different materials that are alternately stacked. An upper surface of the superlattice structure has a plurality of pits, and a sidewall of the pits has a plurality of convex portions and a plurality of concave portions that are alternate. The group III nitride structure fills the pits. A method of fabricating the semiconductor structure includes the following operations. The superlattice structure is formed on the substrate. A carbon layer is deposited on the superlattice structure. The carbon layer and the superlattice structure are etched to form the pits. The group III nitride structure is formed on the superlattice structure and fills the pits.

### CROSS-REFERENCE TO RELATED APPLICATION

This application claims priority to Taiwan Application Serial Number 113147486, filed Dec. 6, 2024, which is herein incorporated by reference in its entirety.

### BACKGROUND

### Field of Invention

The present disclosure relates to a semiconductor structure and a fabricating method of the semiconductor structure.

### Description of Related Art

Generally speaking, during a semiconductor structure process of growing a group III nitride layer on a substrate, the semiconductor structure is prone to bending and/or cracking due to differences in lattice constants and thermal expansion coefficients between the substrate and the group III nitride layer. Therefore, there is an urgent need to develop a semiconductor structure to improve the above problems.

### SUMMARY

The present disclosure provides a semiconductor structure, including a substrate, a superlattice structure disposed on the substrate, and a group III nitride structure disposed on the superlattice structure. The superlattice structure includes a plurality of first group III nitride layers and a plurality of second group III nitride layers that are alternately stacked. The first and second group III nitride layers include different materials. An upper surface of the superlattice structure has a plurality of pits, and a sidewall of the pits has a plurality of convex portions and a plurality of concave portions that are alternate. The group III nitride structure fills the pits.

The present disclosure provides a method of fabricating the semiconductor structure, including the following operations. The superlattice structure is formed on the substrate. A carbon layer is deposited on the superlattice structure. The carbon layer and the superlattice structure are etched to form the pits. The group III nitride structure is formed on the superlattice structure and fills the pits.

### BRIEF DESCRIPTION OF THE DRAWINGS

FIG. 1 is a flow diagram of a method of fabricating a semiconductor structure, in accordance with some embodiments of the present disclosure.

FIGS. 2-3 are cross-sectional views of intermediate stages of fabricating the semiconductor structure, in accordance with some embodiments of the present disclosure.

FIGS. 4A-4B are cross-sectional views of pits, in accordance with some embodiments of the present disclosure.

FIGS. 5-7 are cross-sectional views of intermediate stages of fabricating the semiconductor structure, in accordance with some embodiments of the present disclosure.

### DETAILED DESCRIPTION

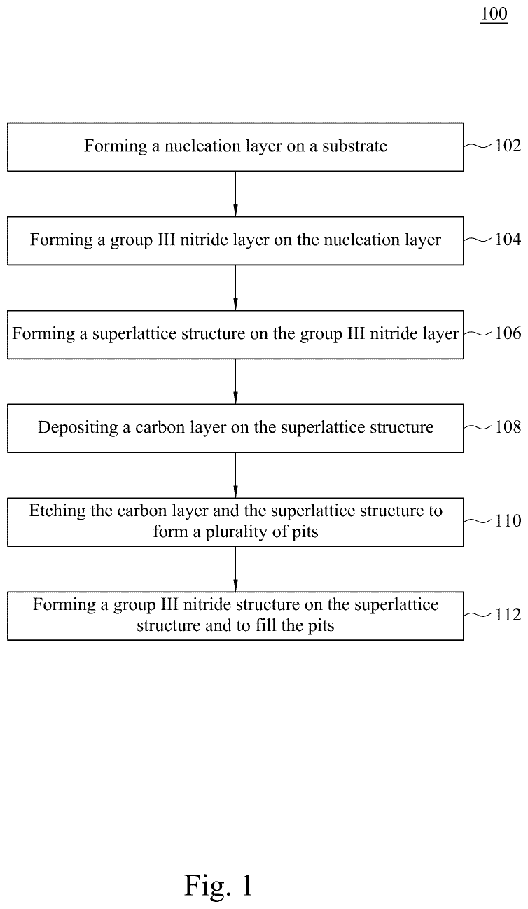

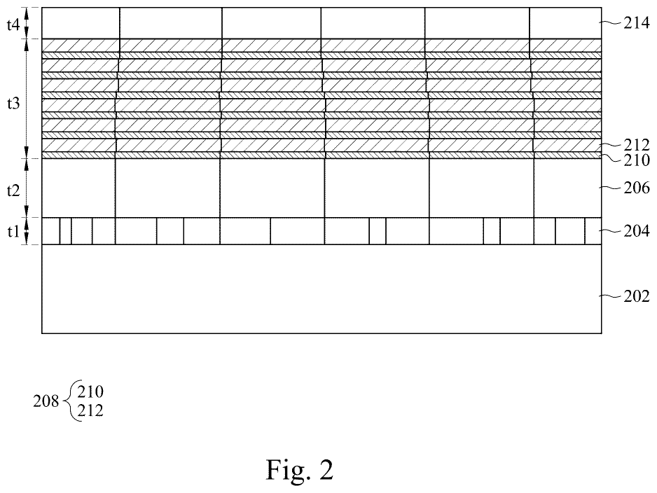

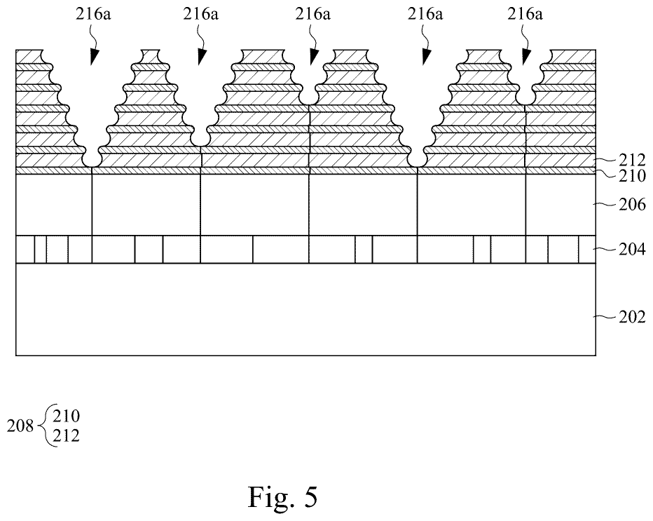

FIG. 1 is a flow diagram of a method 100 of fabricating a semiconductor structure, in accordance with some embodiments of the present disclosure. The method 100 includes operations 102, 104, 106, 108, 110, and 112. FIGS. 2-3 and 5-7 are cross-sectional views of intermediate stages of fabricating the semiconductor structures 200A, 200B, in accordance with some embodiments of the present disclosure. Refer to FIGS. 1 and 2. In operation 102, a nucleation layer 204 is formed on a substrate 202. The nucleation layer 204 is formed by, for example, metal-organic chemical vapor deposition (MOCVD), hydride vapor phase epitaxy (HVPE), molecular beam epitaxy (MBE), sputtering, ionic electroplating, or other suitable epitaxy methods. In some embodiments, the nucleation layer 204 includes a group III nitride, SiC, or carbon, and the group III nitride is, for example AlN, AlGaN, GaN, InAlN, InGaN, or combinations thereof. In some embodiments, a thickness t1 of the nucleation layer 204 is 50 nm to 500 nm, such as 50, 100, 150, 200, 250, 300, 350, 400, 450, 500 nm. In some embodiments, the substrate 202 includes Si, SiC, sapphire, MgO, GaN, ZnO, AlN, Ga₂O₃, Al₂O₃, or combinations thereof, in which Si is, for example, Si having a (111) crystal plane. Refer to FIGS. 1 and 2. In operation 104, a group III nitride layer 206 is formed on the nucleation layer 204. In some embodiments, the group III nitride layer 206 is formed by, for example, MOCVD, HVPE, MBE, sputtering, ionic electroplating, or other suitable epitaxy methods. In some embodiments, the group III nitride layer 206 includes AlGaN, AlN, GaN, InAlN, InGaN, or combinations thereof. In some embodiments, the group III nitride layer 206 includes Al_{X}Ga_{1-X}N, in which X is 0.15 to 1, such as 0.15, 0.2, 0.25, 0.3, 0.35, 0.4, 0.45, 0.5, 0.55, 0.6, 0.65, 0.7, 0.75, 0.8, 0.85, 0.9, 0.95, or 1. In some embodiments, a thickness t2 of the group III nitride layer 206 is 50 nm to 500 nm, such as 50, 100, 150, 200, 250, 300, 350, 400, 450, 500 nm. When the thickness t2 of the group III nitride layer 206 is 50 nm to 500 nm, the dislocation defect densities of the group III nitride layer 206 and other epitaxial layers (e.g., a superlattice structure subsequently formed on the group III nitride layer 206) can be reduced, and the stress control capability of the semiconductor structure is good.

Refer to FIGS. 1 and 2. In operation 106, a superlattice structure 208 is formed on the group III nitride layer 206. As shown in FIG. 2, the superlattice structure 208 is formed on the substrate 202, the nucleation layer 204, and the group III nitride layer 206. The superlattice structure 208 includes a plurality of first group III nitride layers 210 and a plurality of second group III nitride layers 212 that are alternatively stacked, in which the first and second group III nitride layers 210, 212 include different materials. In some embodiments, the first and second group III nitride layers 210, 212 respectively include AlN, AlGaN, GaN, InAlN, InGaN, AlYN, AlScN, or combinations thereof. In some embodiments, a thickness t3 of the superlattice structure 208 is 1000 nm to 2500 nm, such as 1000, 1250, 1500, 1750, 2000, 2250, or 2500 nm. In some embodiments, the first and second group III nitride layers 210, 212 are respectively AlN layer and Al_{X}Ga_{1-X}N layer (X is 0.3 to 0.6, such as 0.3, 0.35, 0.4, 0.45, 0.5, 0.55, or 0.6). In some embodiments, a superlattice structure (not shown) different from the superlattice structure 208 is formed between the superlattice structure 208 and the group III nitride layer 206, in which the superlattice structure includes AlN layer and Al_{Y}Ga_{1-Y}N layer (Y is 0.3 to 0.6, such as 0.3, 0.35, 0.4, 0.45, 0.5, 0.55, or 0.6) that are alternatively stacked, and the second group III nitride layer 212 in the superlattice structure 208 is Al_{X}Ga_{1-X}N layer (X is 0.15 to 0.45, such as 0.15, 0.2, 0.25, 0.3, 0.35, 0.4, or 0.45). In some embodiments, a thickness of the superlattice structure (not shown) is same as the thickness t3 of the superlattice structure 208. In some embodiments, the superlattice structure (not shown) and the superlattice structure 208 are formed by, for example, MOCVD, HVPE, MBE, sputtering, ionic electroplating, or other suitable epitaxy methods. Refer to FIGS. 1 and 2. In operation 108, a carbon layer 214 is deposited on the superlattice structure 208. In some embodiments, the carbon layer 214 is deposited by, for example, the chemical vapor deposition process, the physical vapor deposition process, the atomic layer deposition process, or other suitable deposition process. In some embodiments, depositing the carbon layer 214 on the superlattice structure 208 is depositing the carbon layer 214 by methane gas, ethane gas, propane gas, hexane gas, acetylene gas, ethylene gas, propylene gas, butane gas, butene gas, cyclopentane, cyclopentene, hexene, N(CH₃)₃, or combinations thereof. In some embodiments, the carbon layer 214 includes polycrystalline carbon, amorphous carbon, or a combination thereof, in which polycrystalline carbon includes graphite, aluminum carbide (Al₄C₃), or a combination thereof, and amorphous carbon includes hard carbon, soft carbon, or a combination thereof. In some embodiments, a thickness t4 of the carbon layer 214 is 5 nm to 30 nm, such as 5, 10, 15, 20, 25, or 30 nm.

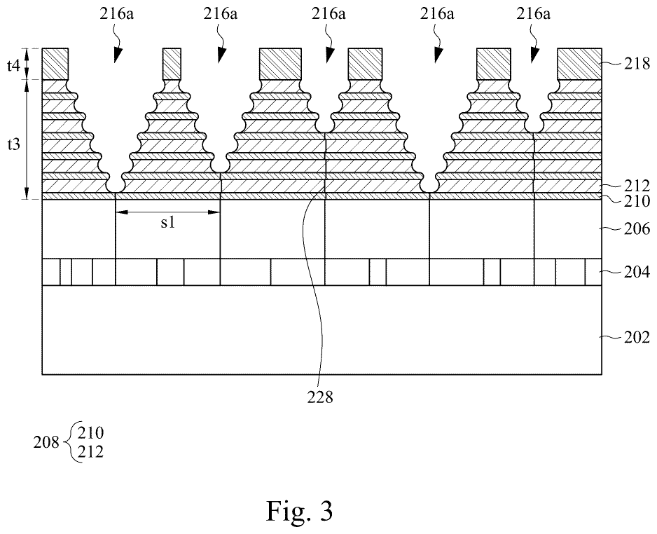

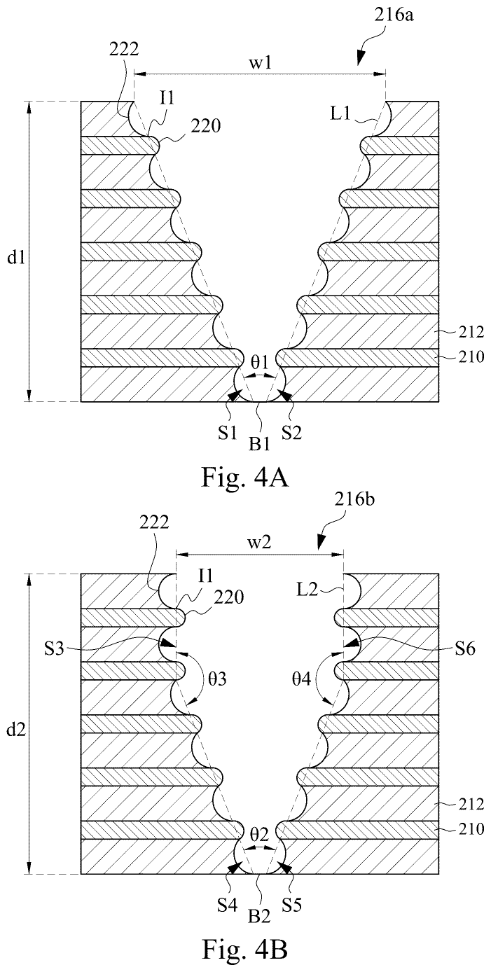

Refer to FIGS. 1-3. In operation 110, the carbon layer 214 and the superlattice structure 208 are etched to form the pits 216a and a carbon layer 218. In some embodiments, etching the carbon layer 214 and the superlattice structure 208 include in-situ etching the carbon layer 214 and the superlattice structure 208. In some embodiments, the carbon layer 214 and the superlattice structure 208 are etched by the dry etching process. In some embodiments, etching the carbon layer 214 and the superlattice structure 208 to form the pits 216a and the carbon layer 218 is performed by chlorine gas and ammonia gas, in which the etching method includes performing in a plasma manner or a thermal dry etching method (the chlorine gas is served as a main etching gas/etching reaction precursor of the superlattice structure 208, and the ammonia gas is served as a main etching gas/etching reaction precursor of the carbon layer 218). In some embodiments, before and after etching the carbon layer 214 and the superlattice structure 208, the thickness t3 of the superlattice structure 208 and the thickness t4 of the carbon layer remain unchanged. In some embodiments, top views of the pits 216a are hexagons. FIGS. 4A-4B are cross-sectional views of the pits 216a, 216b, in accordance with some embodiments of the present disclosure. An enlarge image of one of the pits 216a in FIG. 3 is shown in FIG. 4A. A sidewall of the pits 216a has the convex portions 220 and the concave portions 222 that are alternate. When the sidewall of the pits 216a has the convex and concave portions 220, 222 that are alternate, a surface area of the sidewall of the pits 216a may be increased. Thus, when the layer(s) and the structure(s) on the superlattice structure 208 formed subsequently is/are formed on the superlattice structure 208, the stress control capability of the semiconductor structure may be strengthened, thereby improving the quality and the yield of the semiconductor structure. In some embodiments, opening widths of the pits 216a in a cross-section generally increase from the bottom to the top. In some embodiments, the convex and concave portions 220, 222 have the intersection points 11 in a cross-section of one of the pits 216a, the intersection points 11 are connected to form a virtual line L1, and a shape surrounded by the virtual line L1, an opening of one of the pits 216a, and a bottom B1 of one of the pits 216a is a trapezoid with a wide top and a narrow bottom. In some embodiments, the trapezoid has a first side S1, a second side S2, and the bottom B1, in which an included angle θ1 between the first and second sides S1, S2 is 20 degrees to 120 degrees, such as 20, 30, 40, 50, 60, 70, 80, 90, 100, 110, or 120 degrees. The pits 216a in FIG. 3 may also be pits 216b as shown in FIG. 4B. In some embodiments, the convex and concave portions 220, 222 have the intersection points 11 in a cross-section of one of the pits 216b, the intersection points 11 are connected to form a virtual line L2, and a shape surrounded by the virtual line L2, an opening of one of the pits 216b, and a bottom B2 of one of the pits 216b is a hexagon. In some embodiments, an opening width w2 of a top portion of the hexagon is greater than a width of the bottom B2. In some embodiments, the hexagon has a first side S3, a second side S4, a third side S5, a fourth side S6, and the bottom B2, in which the second side S4 is intersected with the first side S3 and the bottom B2; the bottom B2 is intersected with the second and third sides S4, S5; and the third side S5 is intersected with the bottom B2 and the fourth side S6. Refer to the included angle θ1 between the first and second sides S1, S2 for an included angle θ2 between the second, third sides S4, S5. In some embodiments, an included angle θ3 between the first and second sides S3, S4 and an included angle θ4 between the third and fourth sides S5, S6 are respectively 90 degrees to 170 degrees, such as 90, 100, 110, 120, 130, 140, 150, 160, or 170 degrees. In some embodiments, an opening width w1 of the pits 216a and the opening width w2 of the pits 216b are respectively 20 nm to 500 nm, such as 20, 50, 100, 150, 200, 250, 300, 350, 400, 450, or 500 nm. Refer to FIGS. 2-4. In some embodiments, the thickness t4 of the carbon layer 214 and the etching temperature of the carbon layer 214 and the superlattice structure 208 may affect the etching rate of the carbon layer 214 and the superlattice structure 208, and further affect the opening width w1 and the included angle θ1 of the pits 216a. In some embodiments, the pits 216a have an aspect ratio of 0.5 to 4, such as 0.5, 1, 1.5, 2, 2.5, 3, 3.5, or 4, and the aspect ratio of the pits 216a is a value calculated by dividing a depth d1 of the pits 216a by the opening width w1 of the pits 216a. In some embodiments, the pits 216a are formed on dislocations 228 of the superlattice structure 208. In some embodiments, when spacings s1 of the adjacent dislocations 228 are less than or equal to 200 nm, for example, 10, 20, 40, 60, 80, 100, 120, 140, 160, 180, or 200 nm, the pits 216a have the aspect ratio of 0.5 to 2, for example, 0.5, 0.75, 1, 1.25, 1.5, 1.75, or 2. In some embodiments, when the spacings s1 of the adjacent dislocations 228 are greater than 200 nm, preferably 200 nm to 1200 nm, for example, 200, 300, 400, 500, 600, 700, 800, 900, 1000, 1100, or 1200 nm, the pits 216a have the aspect ratio of 1.5 to 4, for example, 1.5, 1.75, 2, 2.25, 2.5, 2.75, 3, 3.25, 3.5, 3.75, or 4. The carbon layer 218 deposited on the superlattice structure 208 may be served as a protection layer of the superlattice structure 208. Thus, when the carbon layer 214 and the superlattice structure 208 are etched, the thickness t3 of the superlattice structure 208 remains unchanged, thereby forming the pits 216a with high aspect ratios. Forming the pits 216a with high aspect ratios may prevent the dislocation defects from extending to the structures and the layers formed on the superlattice structure 208, such that the quality and the yield of the semiconductor structure may improve. Refer to the embodiments and the effects of the aforementioned pits 216a for the embodiments and the effects of the pits 216b.

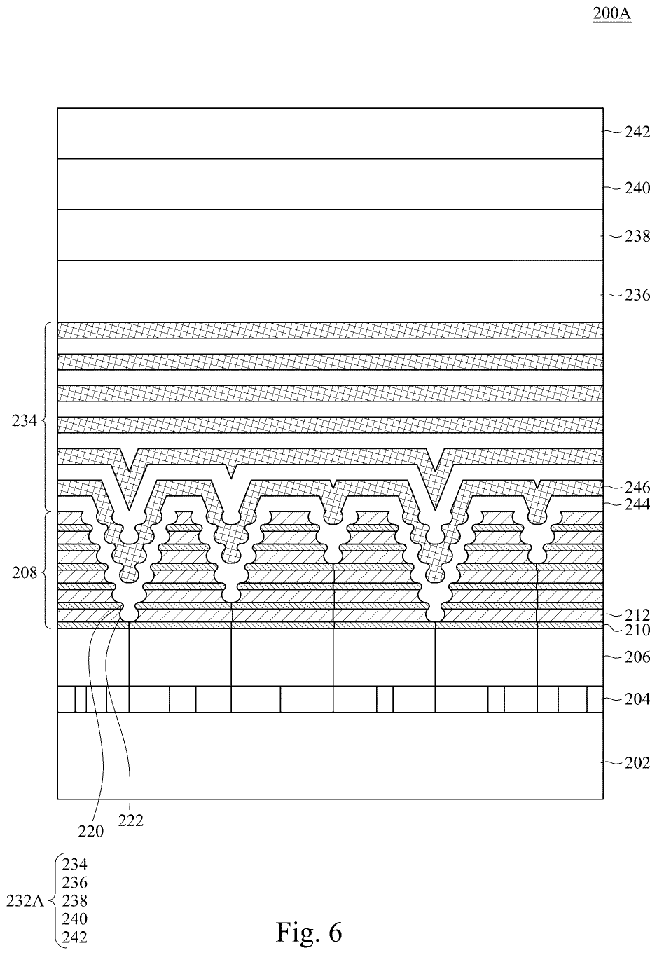

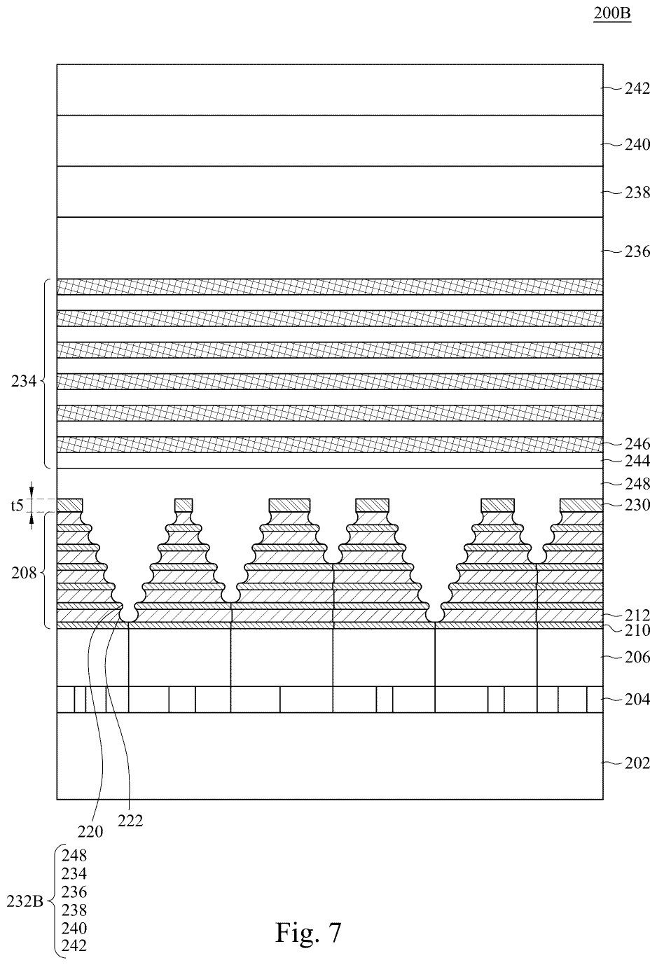

Refer to FIGS. 1-3 and 5. In some embodiments, the method 100 further includes after the carbon layer 214 and the superlattice structure 208 are etched to form the pits 216a, the carbon layer 218 is removed. In some embodiments, removing the carbon layer 218 includes in-situ etching the carbon layer 218. In some embodiments, the carbon layer 218 is removed by the dry etching process, such as removing the carbon layer 218 by nitrogen gas and ammonia gas, in which the etching manner includes performing by the plasma manner or the dry etching manner (the NH-based, NH₂-based related etching reaction precursors is provided via pyrolysis). When removing the carbon layer 218 is performed by nitrogen gas and ammonia gas, nitrogen gas and ammonia gas are reacted with the carbon layer 218 to form HCN gas to remove the carbon layer 218. At the same time, the dislocation defects on the upper surface of the superlattice structure 208 are also repaired. In some embodiments, removing the carbon layer 218 includes completely removing the carbon layer 218 (refer to FIG. 6) or partially removing the carbon layer 218 to form a carbon layer 230 (refer to FIG. 7). In some embodiments, take the thickness t4 of the carbon layer 218 as an example of 30 nm, the partial removal of the carbon layer 218 is to remove the carbon layer 218 between 20 nm and 29 nm, such as 20, 21, 22, 23, 24, 25, 26, 27, 28, or 29 nm. That is, a thickness t5 of the remaining carbon layer 230 is 1 nm to 10 nm, such as 1, 2, 3, 4, 5, 6, 7, 8, 9, or 10 nm, as shown in FIG. 7. When the thickness t5 of the carbon layer 230 is greater than or equal to 5 nm, a surface of the carbon layer 230 is substantially flat. When the thickness t5 of the carbon layer 230 is less than or equal to 3 nm, the surface of the carbon layer 230 forms partially island-like or rugged distribution. The thinner the thickness t5 of the carbon layer 229, the more the contact area proportion between the superlattice structure 208 and the layers formed subsequently on the superlattice structure 208. When the carbon layer 218 is removed by nitrogen gas and ammonia gas, the remaining carbon layer 230 can serve as an epitaxial blocking layer, such that the structures or the layers formed subsequently on the superlattice structure 208 may reduce the dislocation density, thereby enhancing the quality and the yield of the semiconductor structure.

Refer to FIGS. 1 and 5-6. In operation 112, a group III nitride structure 232A is formed on the superlattice structure 208 and fills the pits 216a. In some embodiments, a thickness of the group III nitride structure 232A is 2040 nm to 10000 nm, such as 2040, 2500, 3000, 3500, 4000, 4500, 5000, 5500, 6000, 6500, 7000, 7500, 8000, 8500, 9000, 9500, or 10000 nm. The thickness of the group III nitride structure 232A greater than 9000 nm may be suitable for the application of the 1200 V high voltage electric vehicle. When the thickness of the group III nitride structure 232A is 2040 nm to 5000 nm, the stress control capability of the semiconductor structure may be enhanced, thereby improving the quality and the yield of the semiconductor structure. In some embodiments, the group III nitride structure 232A is formed by, for example, MOCVD, HVPE, MBE, sputtering, ionic electroplating, or other suitable epitaxy methods. When the group III nitride structure 232A is formed on the superlattice structure 208 and fills the pits 216a, the dislocation density of the group III nitride structure 232A decreases and the stress control capability of the semiconductor structure enhances, thereby improving the quality and the yield of the semiconductor structure. In some embodiments, the dislocation density of the group III nitride structure 232A is 2×10⁷ cm⁻² to 8×10⁸ cm⁻², such as 2×10⁷, 4×10⁷, 6×10⁷, 8×10⁷, 1×10⁸, 2×10⁸, 4×10⁸, 5×10⁸, 6×10⁸, or 8×10⁸ cm⁻². Applied to the semiconductor epitaxial structure of the present disclosure, when the dislocation density of the group III nitride structure 232A (device operation area) is less than 5×10⁸ cm⁻², the leakage behavior of the semiconductor device on the wafer may be greatly improved, thereby obtaining a better overall yield. In some embodiments, there are voids in the group III nitride structure 232A. When voids are in the group III nitride structure 232A, the stress of the semiconductor structure may be released, thereby improving the quality and the yield of the semiconductor structure. In some embodiments, the group III nitride structure 232A includes multiple group III nitride layers, in which multiple group III nitride layers can be replaced by a single group III nitride layer. In some embodiments, the group III nitride structure 232A includes AlN, AlGaN, GaN, InAlN, AlYN, AlScN, or combinations thereof. In some embodiments, the group III nitride structure 232A is a superlattice structure 234 (a thickness of 1000 nm to 7000 nm, such as 1000, 1500, 2000, 2500, 3000, 3500, 4000, 4500, 5000, 5500, 6000, 6500, or 7000 nm), a GaN layer 236 (a thickness of 500 nm to 3000 nm, such as 500, 1000, 1500, 2000, 2500, or 3000 nm), a GaN layer 238 (a thickness of 150 nm to 600 nm, such as 150, 300, 450, or 600 nm), a AlGaN layer 240 (a thickness of 10 nm to 35 nm, such as 10, 15, 20, 25, 30, or 35 nm), and a pGaN layer 242 (a thickness of 50 nm to 120 nm, such as 50, 60, 70, 80, 90, 100, 110, or 120 nm) in order from the bottom to the top. In some embodiments, the group III nitride structure 232A may omit the pGaN layer 242. In some embodiments, the pGaN layer 242 includes a nitride of 2A group elements such as Be, Mg, Ca, Sr, Ba, Ra, or combinations thereof and GaN, in which GaN can also be replaced by AlN, Al_{X}Ga_{1-X}N (X is 0.1 to 0.9, such as 0.1, 0.2, 0.3, 0.4, 0.5, 0.6, 0.7, 0.8, or 0.9), SiN, or combinations thereof. If GaN is replaced by AlN, Al_{X}Ga_{1-X}N (X is 0.1 to 0.9), SiN, or combinations thereof, a thickness of the replaced pGaN layer is 3 nm to 100 nm, such as 3, 10, 20, 40, 60, 80, or 100 nm. In some embodiments, the group III nitride structure 232A further includes a portion of superlattice structure 208 between the superlattice structure 234 and the pits 216a. That is, a portion of superlattice structure 208 fills the pits 216a and is in contact with the superlattice structure 234. In some embodiments, the superlattice structure 234 includes a first group III nitride layer 244 and a second group III nitride layer 246 that are alternatively stacked, in which the first and second group III nitride layers 244, 246 with different materials are respectively AlN layer and Al_{X}Ga_{1-X} N layer (X is 0.15 to 0.45, such as 0.15, 0.2, 0.25, 0.3, 0.35, 0.4, or 0.45). In some embodiments, a thickness of the first group III nitride layer 244 is 2 nm to 10 nm, such as 2, 4, 6, 8, or 10 nm, and a thickness of the second group III nitride layer 246 is 5 nm to 40 nm, such as 5, 10, 15, 20, 25, 30, 35, or 40 nm. In some embodiments, the first and second group III nitride layers 244, 246 may be replaced by any one of AlN layer, AlGaN layer, InAlN layer, InGaN layer, or GaN layer, in which the AlGaN layer includes Al_{X}Ga_{1-X}N (X is 0.01 to 0.45, such as 0.01, 0.05, 0.1, 0.15, 0.2, 0.25, 0.3, 0.35, 0.4, or 0.45); the InAlN layer includes In_{X}Al_{1-X}N (X is 0.01 to 0.45, such as 0.01, 0.05, 0.1, 0.15, 0.2, 0.25, 0.3, 0.35, 0.4, or 0.45); and the InGaN layer includes In_{Y}Ga_{1-Y}N (Y is 0.01 to 0.3, such as 0.01, 0.05, 0.1, 0.15, 0.2, 0.25, or 0.3). In some embodiments, the first group III nitride layer 244 is conformally formed on the superlattice structure 208. When the group III nitride structure 232A includes the first and second group III nitride layers 244, 246 in the superlattice structure 234 having the aforementioned thicknesses and Al contents, and the superlattice structure 234 acts as a buffer structure to in contact with the superlattice structure 208 and fills the pits 216a (since the sidewall features of the pits 216a of the superlattice structure 208 causes a greater contact area between the superlattice structures 234, 208), such that the dislocation defects of the group III nitride structure 232A are filtered more efficiently in the group III nitride structure 232A (dislocation defects are reduced) and the stress control capability of the semiconductor structure is enhanced, thereby improving the quality and the yield of the semiconductor structure.

Refer to FIGS. 3, 4A, 4B, and 7. When a portion of the carbon layer 230 is remained on the superlattice structure 208, a group III nitride structure 232B is formed on the superlattice structure 208 and the carbon layer 230 and fills the pits 216a, and it is performed by the selective epitaxy growth (SEG) manner. In detail, when the group III nitride structure 232B is on the superlattice structure 208 and the carbon layer 230 and fills the pits 216a, the group III nitride structure 232B has a relatively fast epitaxial growth rate at the surface of the superlattice structure 208 uncovered by the carbon layer 230 because a surface of the carbon layer 230 can be served as a hard mask to block or slow down the epitaxial growth of the group III nitride structure 232B. When forming the group III nitride structure 232B on the superlattice structure 208 and the carbon layer 230 and to fill the pits 216a is performed by SEG, the dislocation density of the group III nitride structure 232B decreases, thereby improving the quality and the yield of the semiconductor structure. In some embodiments, the group III nitride structure 232B forms an AlGaN layer 248 (Al_{X}Ga_{1-X}N, in which X is 0 to 0.7, such as 0, 0.2, 0.4, 0.6, or 0.7) below the superlattice structure 234 in the group III nitride structure 232A, such that the AlGaN layer 248 is in contact with the superlattice structure 208 and fills all of the pits 216a. In some embodiments, the AlGaN layer 248 fills a portion of pits 216a. When the AlGaN layer 248 fills more than 30% (such as 30, 50, 70, 90, or 100%) of the pits 216a, for example, filling the pits 216a with shallower depth d1, and each pits 216a has different filling proportions, the final surface flatness of the superlattice structure 234 may be controlled and the final warpage of the wafer is controlled after the epitaxy of the semiconductor structure. That is, different filling proportions may acquire different curvature variations during epitaxy. In some embodiments, when the thickness of the AlGaN layer 248 is twice that of the depth d1 of the pits 216a, that is, a thickness of the AlGaN layer 248 is less than 7000 nm, for example, 500, 1000, 2000, 3000, 4000, 5000, 6000, or 7000 nm, the superlattice structure 234 in the group III nitride structure 232B is removed and the AlGaN layer 248 includes Al_{X}Ga_{1-X}N (X is 0 to 0.7, such as 0, 0.2, 0.4, 0.6, or 0.7) or an AlGaN structure with a plurality of AlGaN layers. The Al content of these AlGaN layers is based on 45% to 80% (such as 45, 50, 55, 60, 65, 70, 75, or 80%) as an initial layer condition, and the Al content gradually decreases to 0% to 30%, such as 0, 5, 10, 15, 20, 25, or 30%. In some embodiments, the AlGaN structure includes one, two, three, four, or five AlGaN layer(s). When the AlGaN layer 248 is in contact with the superlattice structure 208 and fills the pits 216a, due to the pits 216a with high aspect ratios and maximized sidewall surface areas of the pits 216a, the aforementioned Al content and the thickness of the AlGaN layer 248 can be applied and the AlGaN layer 248 may act as a main stress control layer. That is, the stress control capability of the semiconductor structure may be enhanced, thereby improving the quality and the yield of the semiconductor structure and applying to more varieties of group III nitride semiconductor structure. Refer to the embodiments and the effects of the group III nitride structure 232A for other embodiments and the effects of the group III nitride structure 232B. The group III nitride structure 232A of FIG. 6 can be replaced with the group III nitride structure 232B of FIG. 7. Similarly, the group III nitride structure 232B of FIG. 7 can be replaced with the group III nitride structure 232A of FIG. 6.

Refer to FIG. 6. The semiconductor structure 200A includes the substrate 202, the superlattice structure 208 disposed on the substrate 202, and the group III nitride structure 232A disposed on the superlattice structure 208. The superlattice structure 208 includes the first and second group III nitride layers 210, 212 that are alternately stacked. The first and second group III nitride layers 210, 212 include different materials. An upper surface of the superlattice structure 208 has the pits, and a sidewall of the pits has the convex portions 220 and the concave portions 222 that are alternate. The group III nitride structure 232A fills the pits. In some embodiments, the semiconductor structure 200A further includes the nucleation layer 204 disposed on the substrate 202 and the group III nitride layer 206 disposed on the nucleation layer 204. Refer to FIG. 7. In some embodiments, the semiconductor structure 200B further includes the carbon layer 230 disposed between the superlattice structure 208 and the group III nitride structure 232B. Refer to the components and the configuration relationships of the aforementioned semiconductor structure 200A for the other components and the configuration relationships of the semiconductor structure 200B. Refer to the embodiments and/or the effects in the aforementioned method 100 of fabricating the semiconductor structure for the embodiments and/or the effects of the substrate 202, the nucleation layer 204, the group III nitride layer 206, the superlattice structure 208, the carbon layer 230, the group III nitride structures 232A, 232B, and the pits.

In summary, in the semiconductor structure and the fabricating method thereof, the carbon layer is deposited on the superlattice structure, such that the pits with high aspect ratios are formed when etching the carbon layer and the superlattice structure, thereby preventing the dislocation defects of the superlattice structure from extending to the group III nitride structure. Besides, a sidewall of the pits has the convex and concave portions that are alternate, which may increase the surface area of the sidewall of the pits, such that the stress control capability of the semiconductor structure may be enhanced when the group III nitride structure is formed on the superlattice structure. Thus, the aforementioned features may prevent the semiconductor structure from bending and/or breaking. In other words, the quality and the yield of the semiconductor structure improves.

What is claimed is:

1. A semiconductor structure, comprising:
a substrate;
a superlattice structure disposed on the substrate, wherein the superlattice structure comprises a plurality of first group III nitride layers and a plurality of second group III nitride layers that are alternatively stacked, the first group III nitride layers and the second group III nitride layers comprise different materials, an upper surface of the superlattice structure has a plurality of pits, and a sidewall of the pits has a plurality of convex portions and a plurality of concave portions that are alternate; and
a group III nitride structure disposed on the superlattice structure and filling the pits.

2. The semiconductor structure of claim 1, wherein the first group III nitride layers and the second group III nitride layers respectively comprise AlN, AlGaN, GaN, InAlN, InGaN, AlYN, AlScN, or combinations thereof.

3. The semiconductor structure of claim 1, wherein the pits have an aspect ratio of 0.5 to 4, and the aspect ratio of the pits is a value calculated by dividing a depth of the pits by an opening width of the pits.

4. The semiconductor structure of claim 1, wherein the convex portions and the concave portions have a plurality of intersection points in a cross-section of one of the pits, the intersection points are connected to form a virtual line, and a shape surrounded by the virtual line, an opening of the one of the pits, and a bottom of the one of the pits is a hexagon or a trapezoid with a wide top and a narrow bottom.

5. The semiconductor structure of claim 1, further comprising:
a carbon layer disposed between the superlattice structure and the group III nitride structure.

6. A method of fabricating a semiconductor structure, comprising:
forming a superlattice structure on a substrate;
depositing a carbon layer on the superlattice structure;
etching the carbon layer and the superlattice structure to form a plurality of pits; and
forming a group III nitride structure on the superlattice structure and to fill the pits.

7. The method of claim 6, wherein depositing the carbon layer on the superlattice structure is depositing the carbon layer by methane gas, ethane gas, propane gas, hexane gas, acetylene gas, ethylene gas, propylene gas, butane gas, butene gas, cyclopentane, cyclopentene, hexene, N(CH₃)₃, or combinations thereof.

8. The method of claim 6, wherein etching the carbon layer and the superlattice structure to form the pits is performed by chlorine gas and ammonia gas.

9. The method of claim 6, further comprising:
after etching the carbon layer and the superlattice structure to form the pits, removing the carbon layer.

10. The method of claim 9, wherein removing the carbon layer is performed by nitrogen gas and ammonia gas.
